(19) United States
(12) Patent Application Publication
(10) Pub. No.: US 2014/0176931 A1
(43) Pub. Date: Jun. 26, 2014

(54) INTERMITTENT TEMPERATURE CONTROL OF MOVABLE OPTICAL ELEMENTS

(71) Applicants: Alton H. Phillips, East Palo Alto, CA (US); Douglas C. Watson, Campbell, CA (US); Travis D. Bow, Belmont, CA (US); Hiroyuki Kondo, Saitama (JP); Atsushi Yamada, Yokohama (JP); Hideo Takino, Tokyo (JP); Hideki Komatsuda, Ageo (JP)

(72) Inventors: Alton H. Phillips, East Palo Alto, CA (US); Douglas C. Watson, Campbell, CA (US); Travis D. Bow, Belmont, CA (US); Hiroyuki Kondo, Saitama (JP); Atsushi Yamada, Yokohama (JP); Hideo Takino, Tokyo (JP); Hideki Komatsuda, Ageo (JP)

(73) Assignee: NIKON CORPORATION, Tokyo (JP)

(21) Appl. No.: 14/237,821

(22) PCT Filed: Aug. 12, 2012
(86) PCT No.: PCT/US2012/049863

§ 371 Date: Feb. 7, 2014

Related U.S. Application Data
(60) Provisional application No. 61/522,378, filed on Aug. 11, 2011.

(51) Int. Cl. G02B 26/08; G03F 7/20

(52) U.S. Cl. CPC G02B 26/0816; G03F 7/702
USPC 355/67; 359/872; 359/845; 359/848

(57) ABSTRACT

An optical system including an optical element, a positioning mechanism configured to position the optical element into an operational position, and a temperature control mechanism configured to intermittently control the temperature of the optical element between operations. By alternatively positioning the optical element between an operational position and a position in thermal contact with the temperature control mechanism, the two mechanisms for positioning and controlling the temperature of the optical element are de-coupled from one another. As a result, the mechanism for each may be optimized In non-exclusive embodiments, the temperature control mechanism may be used to control the temperature of an individual optical element or a plurality of optical elements, such as for example, a fly's eye mirror used in an illumination unit of an EUV lithography tool.

### RELATED APPLICATIONS

This application claims the benefit of U.S. Provisional Application 61/522,378 entitled “Intermittent Temperature Control of Movable Optical Elements” filed Aug. 11, 2011, incorporated herein for all purposes.

### BACKGROUND

1. Field of the Invention

This invention relates to lithography, and more particularly, to the intermittent temperature control of movable optical elements, such as those used in a fly's eye mirror.

2. Description of Related Art

Extreme ultraviolet (EUV) lithography is a known semiconductor manufacturing technology that enables semiconductor wafers with extremely small feature sizes to be fabricated. In a typical EUV lithography tool, an EUV light source is generated from a plasma, such as either a Laser Produced Plasma (LPP) or a Discharge Produced Plasma (DPP). In either case, the EUV light is reflected off a mirror surface and into an illumination unit, which effectively acts as a condenser that collects and uniformly focuses the light onto a reticle. Projection optics then project the image defined by the reticle onto a light-sensitive photoresist material formed on a semiconductor substrate to be patterned. In a series of subsequent chemical and/or etching steps, the pattern defined by the reticle is formed on the substrate under the patterned photoresist. By repeating the above process multiple times, the complex circuitry of semiconductor wafer may be created on the substrate.

The illumination unit typically includes a pair of reflective fly's eye mirrors. Each fly's eye includes a plurality of faceted mirror surfaces arranged in an array. During operation, the radiation from the light source is directed using a collimator onto the mirror surfaces of the first fly's eye. Each of the mirror surfaces reflects a portion of the light onto a corresponding mirror surface on the second fly's eye array. Each of the second fly's eye mirror surfaces is positioned in a pupil plane of a condenser, which condenses the reflected light onto the reticle. With this arrangement, the image field of each mirrored surface of the first fly's eye overlaps at the reticle to form a substantially uniform irradiance pattern.

With both the first and second fly's eye arrays, each of the faceted mirror surfaces need to be individually positioned. In addition, the radiation from the light source typically heats the individual mirrored surfaces to the point where they need to be cooled. If cooling is not applied, then the mirrored surfaces may distort and any optical coatings on the surfaces may be damaged. A number of techniques are known for cooling the individual faceted surfaces of a fly's eye mirror.

In International Application PCT/US2009/050030 for example, a bellows seal, containing a heat-conductive fluid, is provided adjacent the individual faceted surfaces. The issue with this arrangement is that the bellows seal is always in contact with the individual faceted surfaces, even in the operational position during exposure. In addition, the bellows limits both the space available, and the range of motion, of the actuators needed to position the individual faceted surfaces. The bellows are also difficult to manufacturer and attached to the base place of the individual faceted elements.

International Publication WO 2010/037476 describes the use of a bearing between the back of the individual faceted surfaces and a base body. A cooling fluid is circulated through the bearing. In addition, the gap across the bearing is adjusted as needed to improve heat conduction. With this arrangement, the bearing is always in thermal contact with the faceted surfaces, regardless if they are in their operational position or not. As a result, the cooling effect is continuous.

The problem with the aforementioned examples is that the cooling mechanism, in each case, is continuous. As a result, the cooling function interferes with the actuators used for positioning the faceted surfaces, and vice-versa. As a result, both functions are compromised.

### SUMMARY OF THE INVENTION

The aforementioned problems are solved by an optical system including an optical element, a positioning mechanism configured to position the optical element into an operational position, and a temperature control mechanism configured to intermittently control the temperature of the optical element between operations. By alternatively positioning the optical element between an operational position and a position in thermal contact with the temperature control mechanism, the two mechanisms for positioning and controlling the temperature of the optical element are de-coupled from one another. As a result, the mechanism for each may be optimized In alternative embodiments, the temperature control mechanism may be used to control the temperature of an individual optical element or a plurality of optical elements. In another non-exclusive embodiment, the optical system is a fly's eye mirror used in an illumination unit of an EUV lithography tool.

### BRIEF DESCRIPTION OF THE DRAWINGS

The invention may best be understood by reference to the following description taken in conjunction with the accompanying drawings, which illustrate specific embodiments of the invention.

FIG. 1 is a diagram of a EUV lithography tool in accordance with a non-exclusive embodiment of the invention.

FIG. 2 is an optical diagram of an exemplary illumination unit and projection optics in the lithography tool of the present invention.

FIGS. 3A and 3B are exemplary diagrams of the first fly's eye mirror and individual faceted elements in accordance with the principles of the invention.

FIGS. 4A and 4B are exemplary diagrams of the second fly's eye and individual faceted optical elements in accordance with the principles of the invention.

FIGS. 5A and 5B illustrate a non-exclusive embodiments of an intermittent temperature control element used for the individual faceted optical elements of a fly's eye mirror in accordance with the principles of the present invention.

FIGS. 5C and 5D illustrate another non-exclusive embodiments of an intermittent temperature control element used for the individual faceted optical elements of a fly's eye mirror in accordance with the principles of the present invention.

FIGS. 6A and 6B illustrate yet another non-exclusive embodiment of an intermittent temperature control element used for the individual faceted optical elements of a fly's eye mirror in accordance with the principles of the present invention.

FIGS. 7A and 7B illustrate a non-exclusive embodiment of an intermittent temperature control element used for the individual faceted optical elements of a fly's eye mirror in accordance with the principles of the present invention.

FIGS. 8A and 8B illustrate another non-exclusive embodiment of an intermittent temperature control element used for the individual faceted optical elements of a fly's eye mirror in accordance with the principles of the present invention.

FIGS. 9A and 9B illustrate yet another non-exclusive embodiment of an intermittent temperature control element used for the individual faceted optical elements of a fly's eye mirror in accordance with the principles of the present invention.

FIGS. 10A through 10C illustrate various non-exclusive embodiments of post-shaped temperature control mechanisms in accordance with the principles of the present invention.

FIGS. 11A and 11B are flow charts that outline a process for designing and making a substrate device.

It should be noted that like reference numbers refer to like elements in the figures.

The above-listed figures are illustrative and are provided as merely examples of embodiments for implementing the various principles and features of the present invention. It should be understood that the features and principles of the present invention may be implemented in a variety of other embodiments and the specific embodiments as illustrated in the Figures should in no way be construed as limiting the scope of the invention.

### DETAILED DESCRIPTION OF SPECIFIC EMBODIMENTS

The invention will now be described in detail with reference to various embodiments thereof as illustrated in the accompanying drawings. In the following description, specific details are set forth in order to provide a thorough understanding of the invention. It will be apparent, however, to one skilled in the art, that the invention may be practiced without using some of the implementation details set forth herein. It should also be understood that well known operations have not been described in detail in order to not unnecessarily obscure the invention.

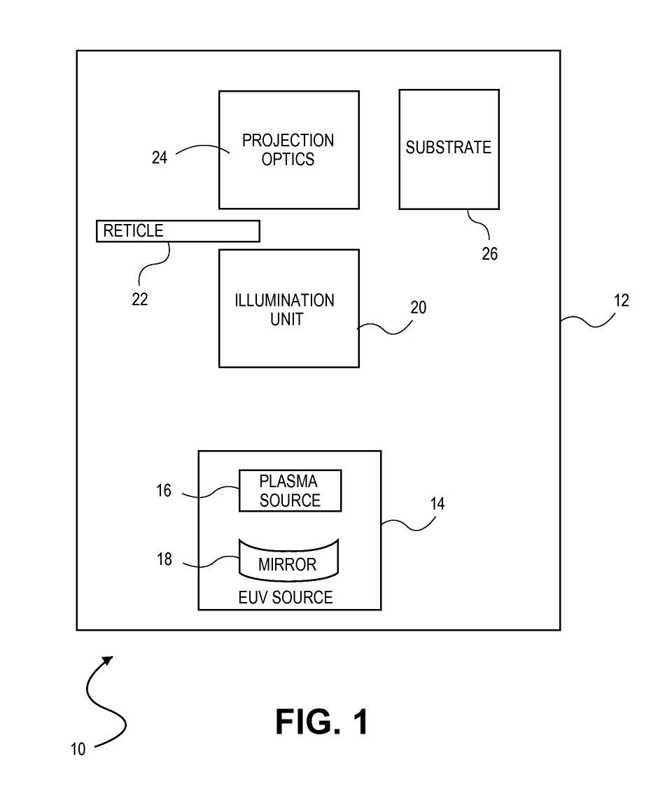

Referring to FIG. 1, a diagram of a EUV lithography tool in accordance with a non-exclusive embodiment of the invention is shown. The tool 10 includes, within a vacuum chamber 12, an extreme ultraviolet (EUV) light source 14 including a plasma source 16 and a mirror 18. The tool 10 also includes an illumination unit 20, a reticle 22, and projection optics 24. During operation, EUV light generated by the plasma source 16 is reflected off the mirror 18 and into the illumination unit 20, which effectively acts as a condenser that collects and uniformly focuses the EUV light onto the reticle 22. The image defined by the reticle is then projected by the projection optics 24 onto a light-sensitive photoresist formed on a substrate 26, such as a semiconductor wafer, to be patterned.

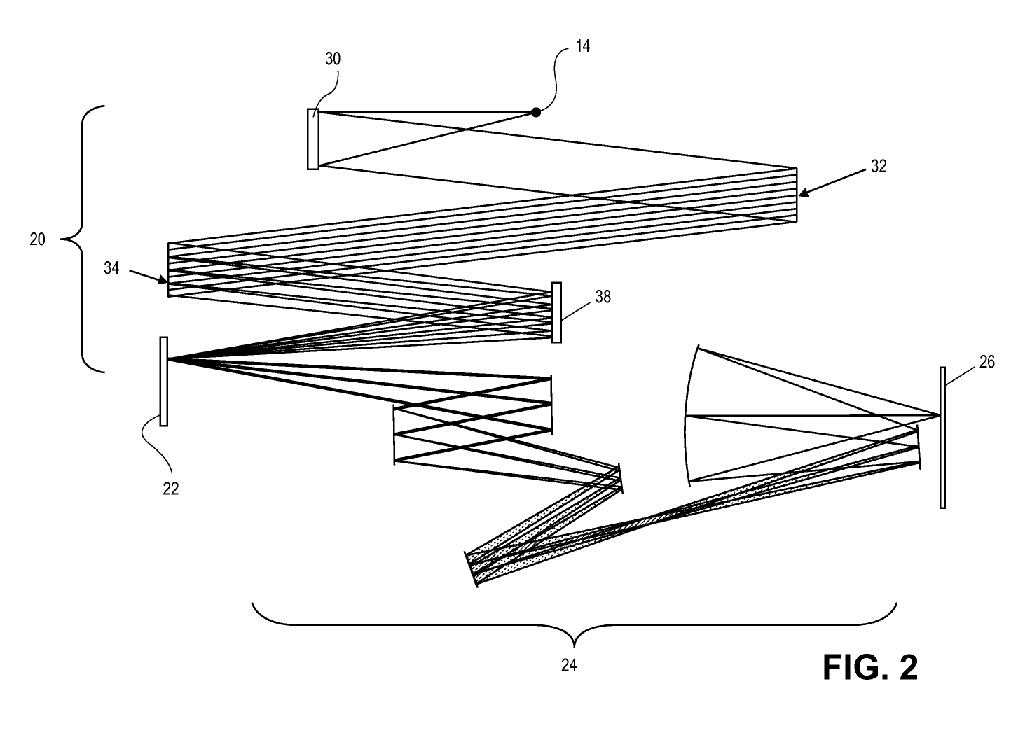

Referring to FIG. 2, an optical diagram of the illumination unit 20 and projection optics 24 in accordance with a non-exclusive embodiment of the invention is shown. The illumination unit 20 includes a first collimator 30, a first fly's eye mirror 32, a second fly's eye mirror 34, and a condenser 38. During operation, the EUV light from the source 14 is reflected off the first fly's eye mirror 32 after being collimated by collimator 30. The faceted mirror surfaces of the first fly's eye 32 forms images of the source 14 at each of the faceted mirror surfaces of the second fly's eye 34. In response, the faceted mirror surfaces of the second fly's eye 34 reflect a uniform image of the first fly's eye 32, through the condenser 38, onto the reticle 22. The pattern defined by the reticle 22 is imaged by the projection optics onto the substrate 26, which is positioned at the image plane of the substrate 26.

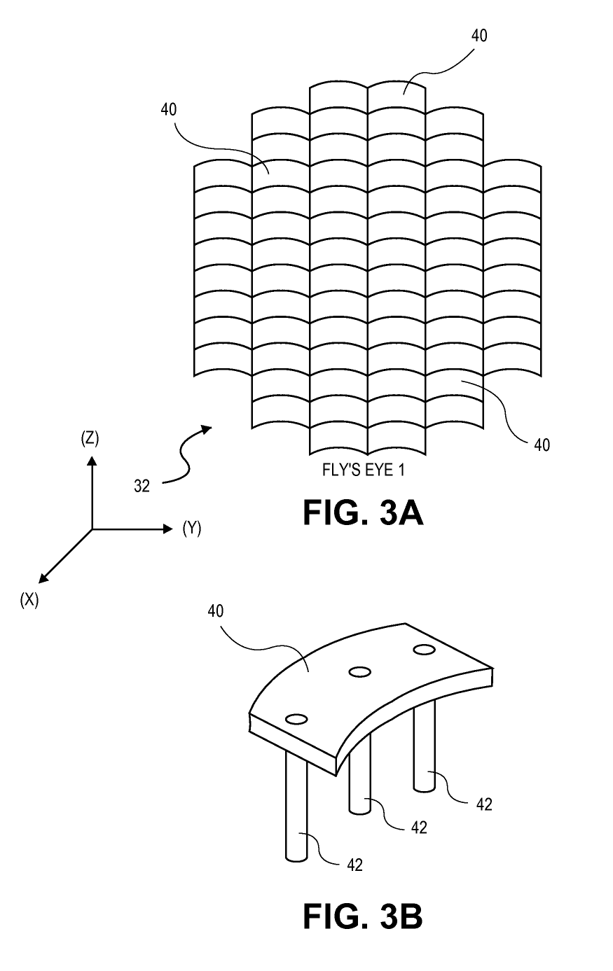

Referring to FIG. 3A, an exemplary diagram of the first fly's eye 32 is shown. The first fly's eye 32 includes a plurality of individual optical elements 40, such as faceted reflective surfaces, arranged in an array. As best illustrated in FIG. 3B, each of the optical elements 40 is a curved or crescent shaped reflective surface, such as a mirror. Three actuators 42 are used to individually position each element 40 in three degrees of freedom θX, θY and Z, while constraining movement in the X, Y and θZ degrees of freedom.

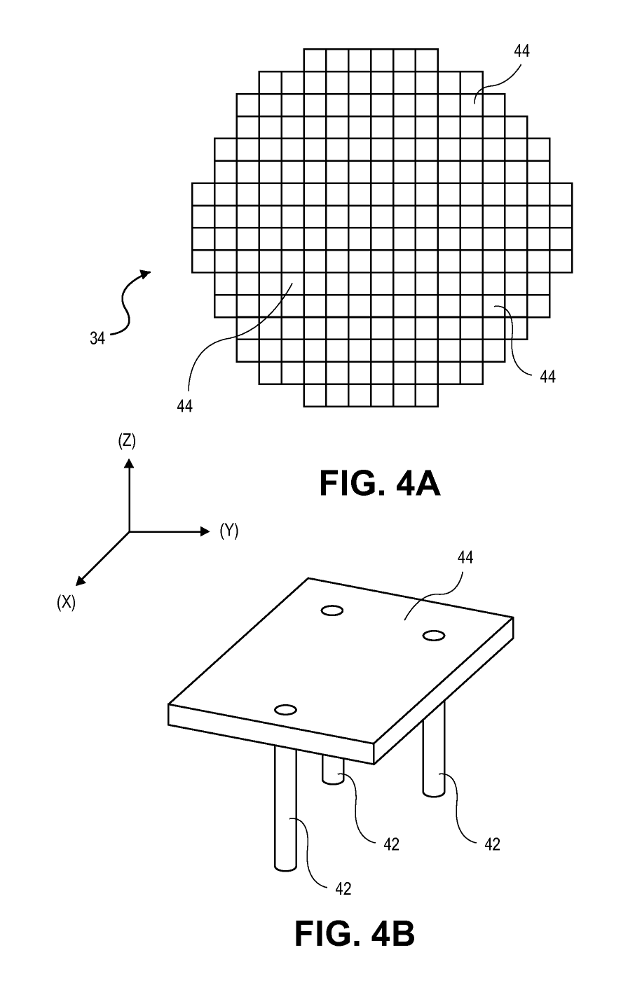

Referring to FIG. 4A, an exemplary diagram of the second fly's eye 34 is shown. The second fly's eye 34 includes a plurality of individual optical elements 44, such faceted reflective surfaces, arranged in an array. As best illustrated in FIG. 4B, each of the optical elements 44 is a square or rectangular shaped surface, such as a mirror. Three actuators 42 are used to individually position each element 44 in three degrees of freedom θX, θY and Z, while constraining movement in the X, Y and θZ degrees of freedom.

It should be noted that curved/crescent or square/rectangular shaped optical elements 40/42 as illustrated in FIGS. 3A and 3B are merely exemplary. The present invention contemplates that the optical elements 40/42 may be any shape, including, but not limited to, curved, crescent, square, rectangular, circular; or oval for example.

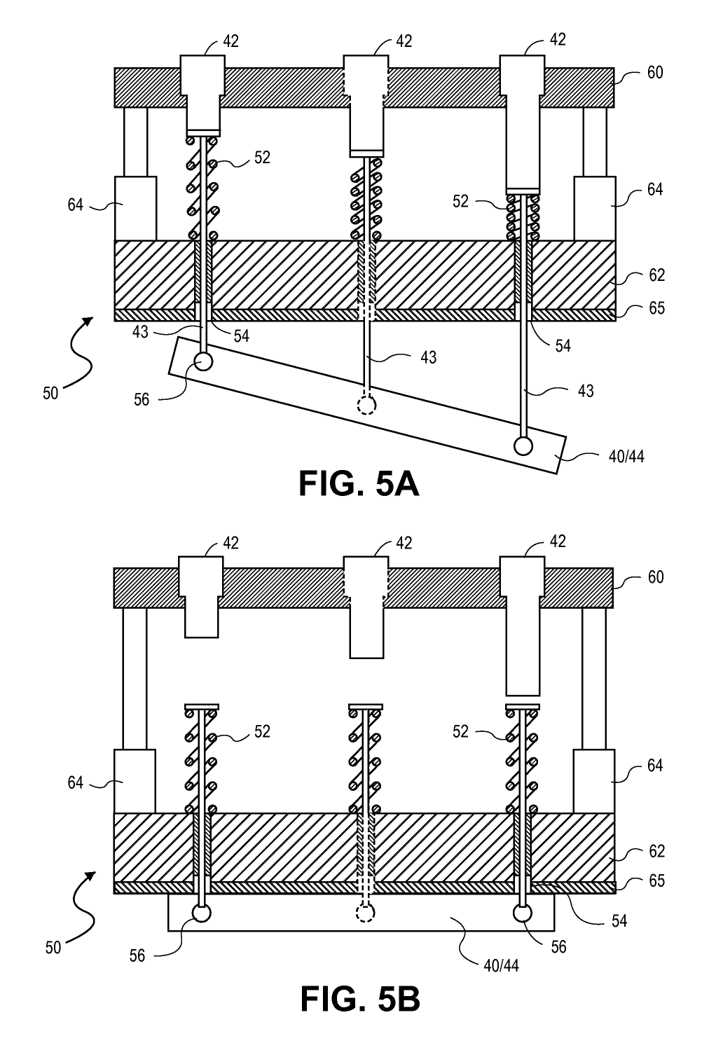

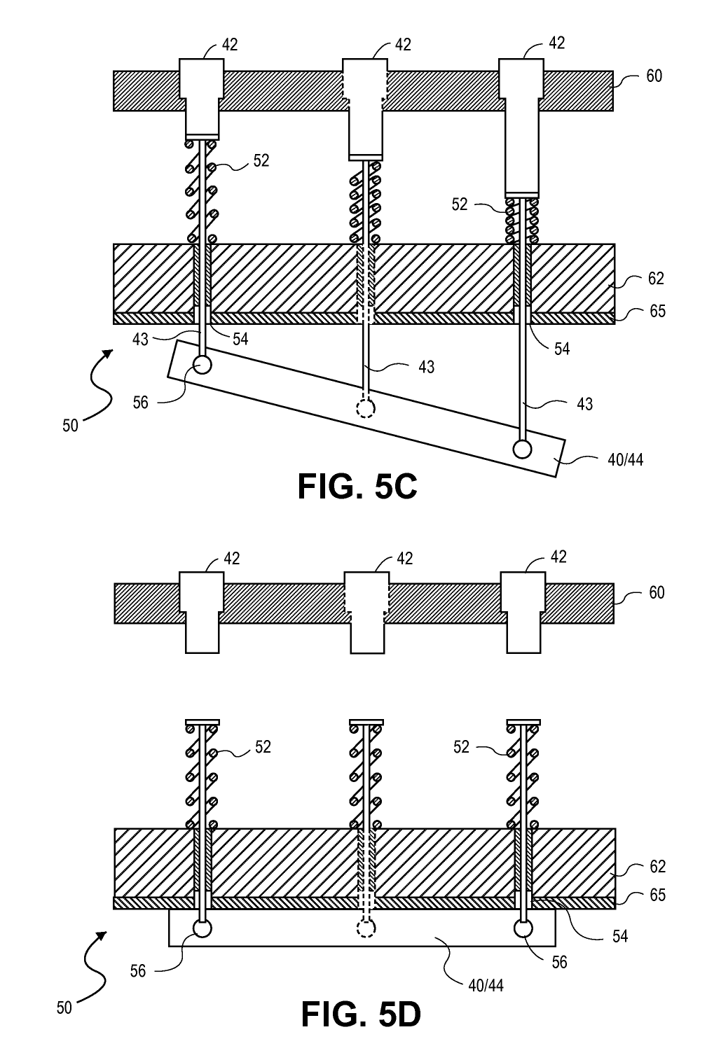

Referring to FIGS. 5A and 5B, a non-exclusive embodiment of an arrangement 50 for the intermittent temperature control of an individual optical element 40/44 is shown. As best illustrated in FIG. 5A, the individual optical element 40/44 is positioned in three degrees of freedom θX, θY and Z by three positioning mechanisms, each including an actuator 42, an actuator rod 43, a compression spring 52, and a guide bearing 54. The actuator rod 43 passes through a temperature control element 62 and is connected to the optical element 40/44 by ball joint 56. As best illustrated in FIG. 5B, the optical element 40/42 is intermittently positioned adjacent to or in contact with a temperature control element 62 by second actuators 64, which move the actuator plate 60 up and down relative to the temperature control element 62.

During exposure, the second actuators 64 are retracted, allowing the actuators 42 and rods 43 to position the optical element 40/44 in three degrees of freedom θX, θY and Z, as illustrated in FIG. 5A. During exchanges of the substrate 26, however, the actuators 64 raise the actuator plate 60, causing the actuators 42 and rods 43 to de-couple from the compression springs 52. As a result, the compression springs 52 pull the optical element 40/44 adjacent to or in contact with the temperature control element 62, which may either cool or heat the optical element 40/44 as needed.

In an optional embodiment, the temperature control element 62 includes a surface 65 that helps facilitate heat transfer between the optical element 40/44 and the temperature control element 62. In various embodiments, the surface 65 is made of vacuum grease, a liquid metal such as but not limited to a gallium-indium eutectic, a fluidic layer of gas, such as oxygen or hydrogen, or an ionic liquid. In one non-exclusive example, the surface 65 is maintained by providing a fluid flow of a noble gas, such as helium, across the surface of the temperature control element 62.

For the sake of simplicity, the actuator plate 60 and the actuators 64 are shown as dedicated to the individual optical element 40/44 as illustrated in FIGS. 5A and 5B. In variations of the above-described embodiment, the actuator plate 60 and the actuators 64, however, can be shared among all or a group of the individual optical elements 40/44 per fly's eye 32/34 respectively.

Referring to FIGS. 5C, a variation of embodiment of FIGS. 5A and 5B is shown. In this embodiment, the second actuators 64 are removed. Instead, the three actuators 42 are used as both (i) the positioning elements for positioning the optical element 40/44 during exposure as illustrated in FIG. 5C and (ii) temperature control elements for intermittently positioning the optical element 40/44 adjacent to or in contact with the temperature control element 62 as illustrated in FIG. 5D. In the latter case, the actuators 42 are retracted, causing the actuators 42 to decouple from the compression springs 52. As a result, the compression springs 52 pull the optical element 40/44 upward, adjacent to or in contact with the temperature control element 62.

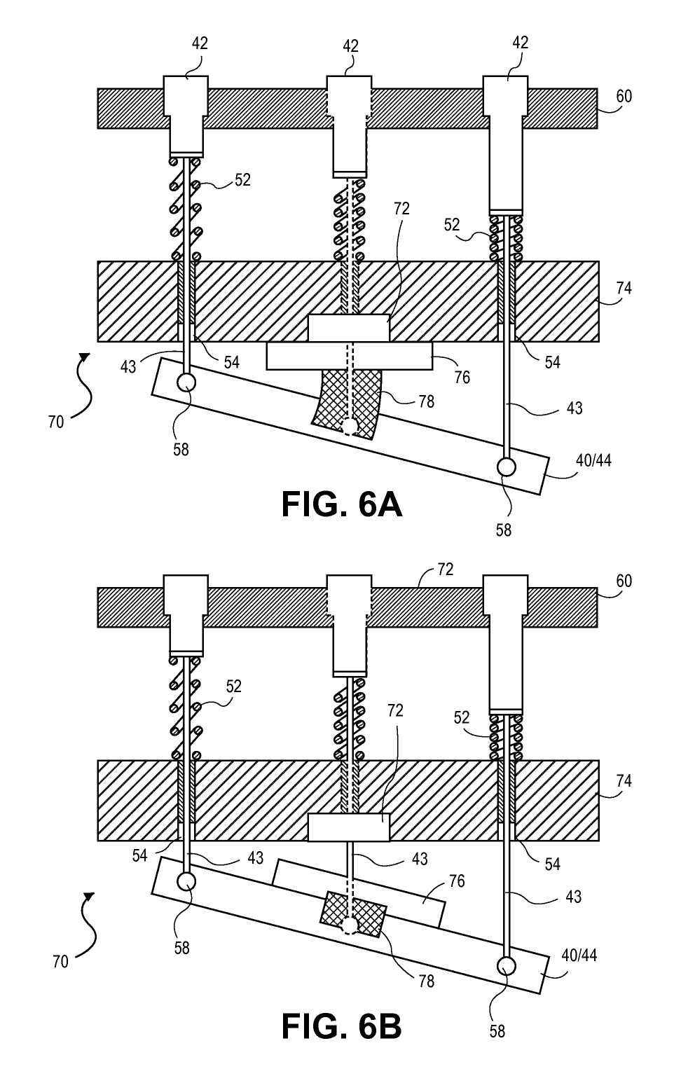

Referring to FIGS. 6A and 6B, another non-exclusive embodiment of an arrangement 70 for the intermittent temperature control of an individual optical element 40/44 is shown. As best illustrated in FIG. 6A, the individual optical element 40/44 is positioned in three degrees of freedom θX, θY and Z by three positioning mechanisms, each including an actuator 42, an actuator rod 43, a compression spring 52, a guide bearing 54, and a ball joint 58. The temperature control mechanism includes an electro-magnet 72 provided in a base plate 74 and a temperature control element 76, such as a copper plate, resiliently attached to the optical element 40/44 using a resilient element 78, such as a spring or elastic material.

By cycling the electro-magnet 72 on and off, the position of the temperature control element 76 is controlled. During exposure periods for example, the electro-magnet 72 is turned on. As a result, the temperature control element 76 is separated from the optical element 40/44 and attracted to base plate 74, as illustrated in FIG. 6A. During exchanges of the substrate 26, the electro-magnet 72 is turned off. As a result, the resilient element 78 pulls the temperature control element 76 into contact with the optical element 40/44, which may either cool or heat the optical element 40/44 as needed.

In an alternative embodiment, the resilient element 78 is made from a thermally conductive material, such as a metal. During exposure operations with this embodiment, the electro-magnet 72 is deactivated, as illustrated in FIG. 6B. This causes the resilient element 76 to pull the temperature control element 76 into contact with the back surface of the optical element 40/44, creating a thermal mass or thermal “capacitor” that either transfers heat or cools the optical element 40/44 as needed. During exchange of the substrate 26, the electro-magnet 72 is turned on, attracting the temperature control element 76 into contact with the base plate 74, allowing the transfer of thermal energy from the element 76 into the base plate 74.

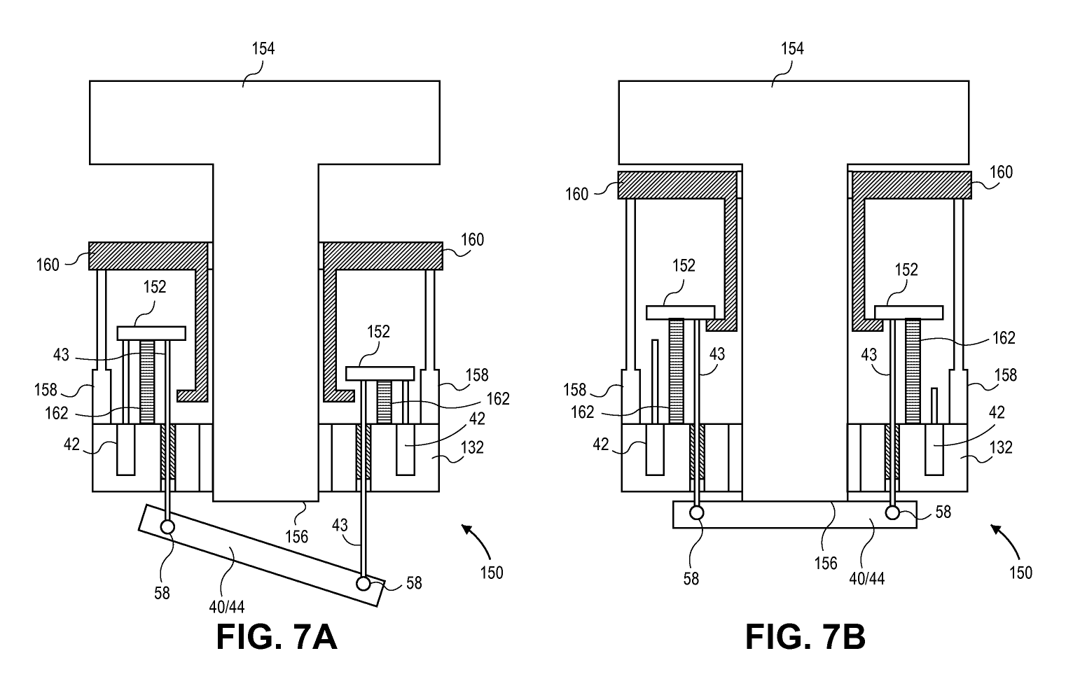

Referring to FIGS. 7A and 7B, another non-exclusive embodiment of an arrangement 150 for the intermittent temperature control of an individual optical element 40/44 is shown. In this embodiment, the optical element 40/44 is selectively positioned in three degrees of freedom θX, θY and Z by three positioning mechanisms, each including an actuator 42, an actuator rod 43, ball joint 58, and rod-head 152. The actuators 42 are embedded in or affixed to a base plate 132.

A temperature control mechanism, including post-shaped structure 154, with a thermally conductive surface 156, is provided through a recess in the base plate 132. In addition, the temperature control mechanism includes hook-plate actuators 158 and a hook-plate 160. The hook-plate actuators 158 are embedded in or affixed to the base plate 132. The hook-plate 160, which is moved up and down relative to the base plate 132 by hook-plate actuators 158, is designed to selectively engage the rod-heads 152. Resilient elements 162 are provided between the base plate 132 and each of the rod heads 152. In a non-exclusive embodiment, the resilient elements 162 are an extension spring.

It should be noted that in FIG. 7A and FIG. 7B, only two of the three positioning mechanisms, actuators 158 and resilient elements 162, are illustrated. In each case, the third element is provided behind the post structure 154, and therefore, is not illustrated for the sake of simplicity. Also in another embodiment, three actuators do not necessarily have to be used. For instance, the third actuator could be “passive”, such as a manually adjusted screw or a rod machined to a predetermined length.

During wafer exposures, as illustrated in FIG. 7A, the hook-plate actuators 158 are in a retracted position. As a result, the hook-plate 160 is not engaged with the corresponding rod-heads 152. The resilient elements 162 provide a resilient force on the rod-heads 152, pulling or forcing the rod-heads 152 into contact with the actuators 42 respectively. As a result, the actuators 42 are free to position the optical element 40/44 in the three degrees of freedom θX, θY and Z. In embodiments where the third actuator is passive, then the optical element 40/44 can be positioned in the θX, θY degrees of freedom.

During wafer exchanges, as illustrated in FIG. 7B, the hook-plate actuators 158 are in an extended position, causing (i) the hook-plate 160 to engage and lift the rod-heads 152 upward and (ii) the actuators 42 to disengage from the rod-heads 152. The resilient elements 162 provide a resilient force on the rod-heads 152, as to force the rod-heads 152 to engage the hook-plate 160. As a result, the actuator rods 43 pull the optical element 40/44 upward, positioning the element adjacent to or in contact with the thermally conductive surface 156 of the post structure 154.

The embodiment of FIG. 7A and FIG. 7B offer several advantages. The actuators 42 are used just for positioning the optical element 40/44 in the two θX, θY or three degrees of freedom θX, θY and Z only during wafer exposure. The hook-plate actuators 158, on the other hand, are used for positioning the element 40/44 adjacent to or in contact with the thermally conductive surface 156 during wafer exchanges. Since two different sets of actuators are used for cycling the optical elements 40/44 between the exposure position and the cooling position, reliability is improved. In addition, the hook-plate actuators 156 can be made sufficiently large and strong to eliminate the need of a pre-load element, such as magnets, that may otherwise be needed to hold the optical element 40/44 adjacent to or in contact with the thermally conductive surface 156.

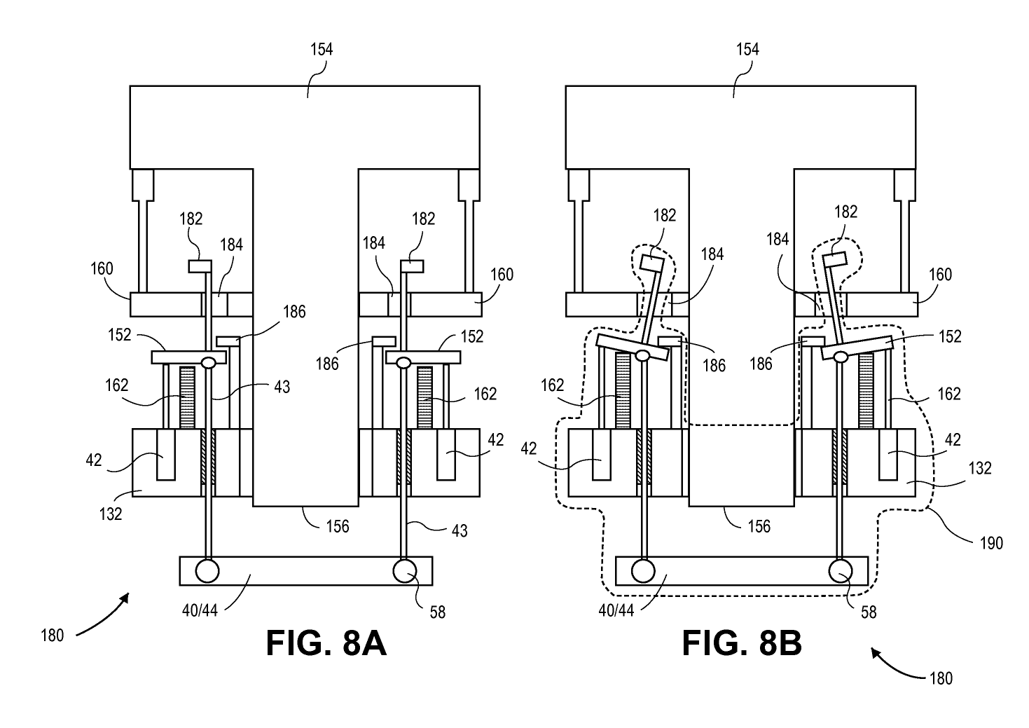

Referring to FIGS. 8A and 8B, another non-exclusive embodiment similar to the arrangement 150 as illustrated in FIGS. 7A and 7B is shown. With this embodiment 180, however, the optical element 40/44 and base plate 132 are removable for service and/or repair, avoiding the requirement of dis-assembling the entire structure.

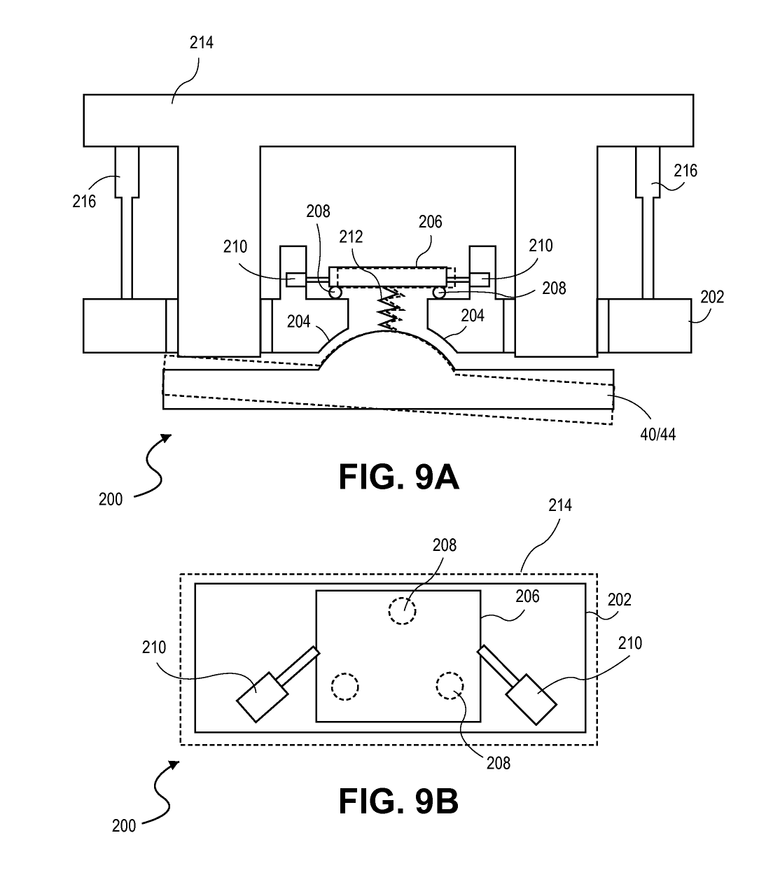

As illustrated in FIG. 8A, the embodiment 180 includes hooks 182 extending upward from rod heads 152 through recesses 184 formed in the hook-plate 160. In this position, the optical element 40/44 may be positioned in the three degrees of freedom θX, θY and Z as illustrated in FIG. 7A or adjacent to or in contact with the thermally conductive surface 156 of the post structure 154 as illustrated in FIG. 7B. To remove the optical element 40/44 and base plate 132, the rod-heads 152 are pushed upward by extending the actuators 42, as illustrated in FIG. 8B. As the rod-heads move upward, the side of the rod-heads 152, opposite the actuators 42, contacts the stops 186. As a result, hooks 182 are rotated as the rod-heads 152 tilt, allowing the hooks 182 to pass through the recess regions 184. The entire sub-assembly 190 (as represented by the dashed line in FIG. 9B), including the optical element 40/44, base plate 132, as well as those elements connected either directly or indirectly to the base plate 132, can therefore be removed. This feature facilitates the repair and/or replacement of the optical element 40/44, or any of the other components on the base plate 132, while keeping the temperature control mechanism, including the post structure 154, intact.

Referring to FIGS. 9A and 9B, side and top views of yet another non-exclusive embodiment for the intermittent temperature control of an individual optical element 40/44 is shown. This embodiment 200 includes a base plate 202 defining a ball joint 204, an optical element 40/44 having a ball-shaped back surface designed to fit into the ball joint 204, a positioning plate 206 positioned on the base plate 202 using sliding elements 208, such as balls, actuators 210 for positioning the plate 206 on the base plate 202, and a resilient element 212, such as a spring, for resiliently attaching the optical element 40/44 to the positioning plate 206. The arrangement 200 further includes a double-post structure 214 that is positioned up and down relative to the base plate 202 using one or more actuators 216. In the non-exclusive embodiment illustrated in FIG. 9A, two actuators 216 are illustrated. In various other embodiments, a single actuator 216, or more than two actuators 216, may be used.

During exposure, the actuators 216 are extended, positioning the post structure 214 away from the optical element 40/44. As a result, the resilient element 212 pulls the optical element 40/44 upward, so that its ball-shaped back surface fits into the ball joint 204 defined by the base plate 202. The actuators 210 are responsible for positioning the plate 206 in the X and Y directions. By moving the positioning plate 206, the position of the optical element 40/44 is controlled in two degrees of freedom, θX, θY, as illustrated by the dashed outline of the element 40/44.

During substrate exchanges, the actuators 216 are retracted, causing the post structure 214 to be positioned downward, pushing the optical element 40/44 into a temperature control position, as illustrated by the solid outline of the element 40/44. When the actuators 216 are once again extended, the post structure 214 is retracted. The optical element 40/44 then returns to its previous position, as controlled by the position plate 206 and the actuators 210.

The advantage of this embodiment 200 is that the optical element 40/44 does not have to be repositioned for the next exposure following a temperature control cycle, unless the actuators 210 are specifically used to adjust the position. With this embodiment, the actuators 210 can be made relatively small and do not need to be very powerful or strong since they are designed to move just the positioning element 206, and not the optical element 40/44 directly. Also since the actuators 210 work in cooperation with the ball joint 204, only two, instead of three, of the actuators 210 are needed.

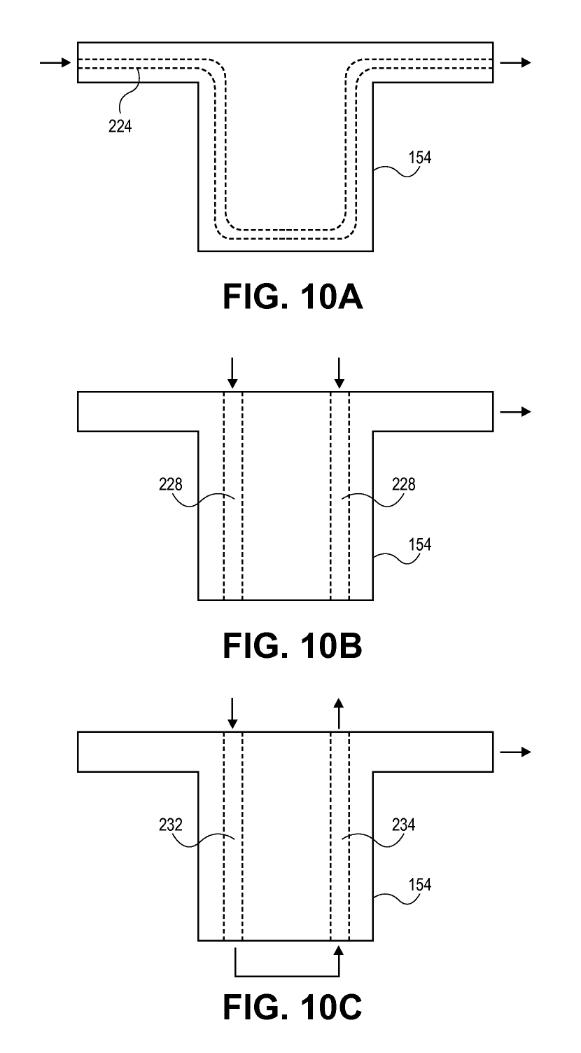

Referring to FIGS. 10A through 10C, various non-exclusive embodiments of post-shaped temperature control mechanisms in accordance with the principles of the present invention are shown. In FIG. 10A, a post structure 154 with a conduit 224 is illustrated. In this embodiment, a temperature control fluid, such as a cooling or heating gas or liquid, is passed from an inlet, through the conduit 224, which runs along the bottom of the post which comes in contact with or adjacent to the optical element 40/44, and then through an outlet.

In FIG. 10B, another post structure 154 is illustrated. The post structure 154 includes two passage ways 228, both providing a temperature control fluid through the post structure 154 and in contact with the optical element 40/44.

In the FIG. 10C embodiment, the post structure 154 includes a first inlet passage 232 for providing a temperature control fluid through the post structure 154 and in contact with optical element 40/44 and a second return passage 234 for removing the temperature control fluid from the optical element 40/44 through the post structure 154.

It should be noted that the embodiments illustrated in FIGS. 10A through 10C each illustrate a temperature control element with a single post. It should be understood that each of these embodiments can also be used with temperature control elements including multiple posts, such as the post 214 illustrated in the FIG. 9A and 9B embodiment.

Furthermore, the fluid used in any of the embodiments 10A through 10C may vary in accordance with different embodiments. For example, with the FIG. 10A embodiment, the fluid may be a liquid, such as water or ammonia, or a gas. Alternatively for the embodiments of FIGS. 10B and 10C, the fluid can be a gas, such as oxygen, hydrogen, or any of the noble gases. In yet another non-exclusive embodiment for FIGS. 10B and 10C, the fluid is a gas, that is used to create a conductive thermal layer adjacent the temperature control element, which may also fill the interstitial spaces on the surface of the optical element 40/44, thereby reducing thermal contact resistance in a vacuum. Furthermore, in each of the embodiments provided above, a one-to-one relationship between the optical element 40/44 and the positioning mechanism the temperature control mechanism is described. It should be understood, however, that in some embodiments, it may be useful or beneficial for a positioning mechanism to position a plurality of the optical elements during exposure operations and temperature control mechanism to intermittently control the temperature of a plurality of the optical elements between exposure operations. For example, in each of the above-described embodiments, the various post structures are shown individual to each optical element 40/44. It should be understood, however, that in alternative embodiments, each of the post structures may be a continuous structure with multiple posts that are used in cooperation with wither all the optical elements 40/44 or some subset of the optical elements 40/44 of the fly's eyes 32/34 respectively.

Fly's eye optical element 32/34 will typically have hundreds of individual optical elements 40/44, each individually positioned by two or three actuators 42 respectively. With all of the embodiments described above, the mechanisms for positioning and controlling the temperature of each of the optical elements 40/44 are de-coupled from one another. As a result, the mechanisms for positioning and temperature control may each be optimized since the two do not interfere with one another.

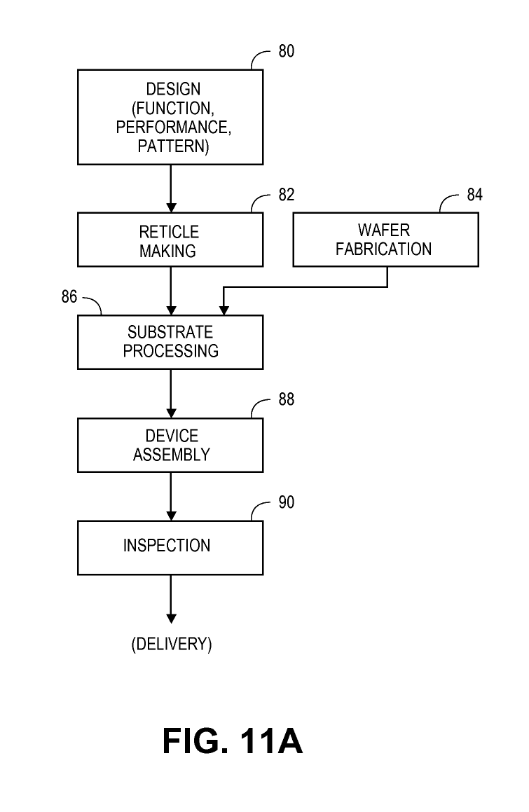

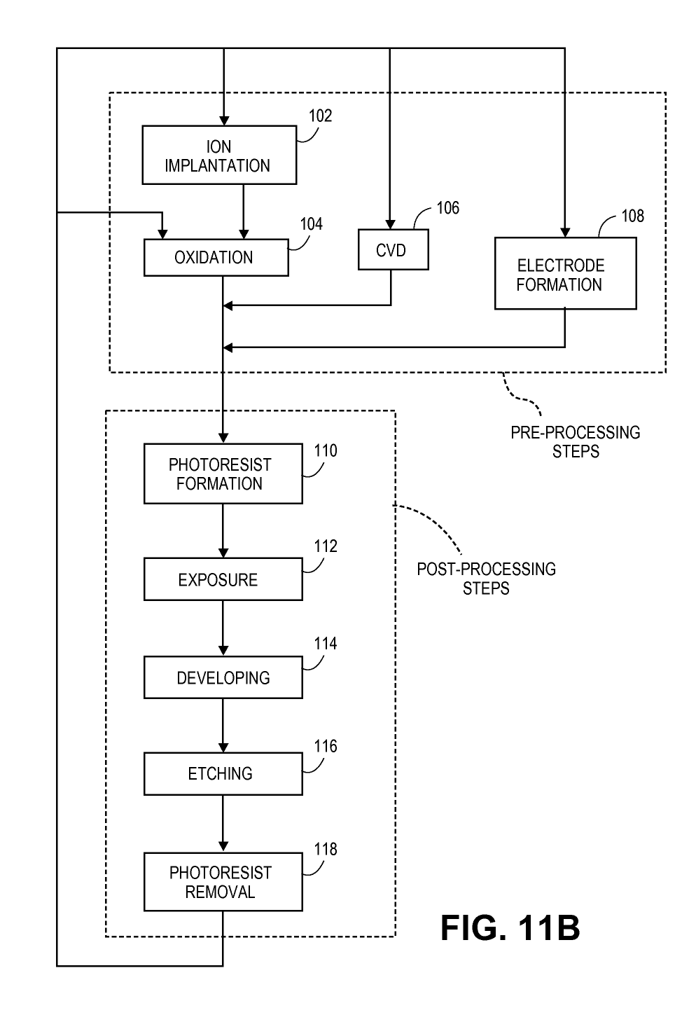

Devices, such as semiconductor die on a wafer or LCD panels, are fabricated by the process shown generally in FIG. 11A. In step 80 the function and performance characteristics of the device are designed. In the next step 82, one or more reticles, each defining a pattern, are developed according with the previous step. In a related step 84 a “blank” substrate, such as a semiconductor wafer, is made and prepared for processing. The substrate is then processed in step 86 at least partially using the photolithography tool 10 as described herein. In step 88, the substrate is diced and assembled and then inspected in step 90.

In each of embodiments illustrated in FIGS. 3A, 3B, 4A, 4B, 5A-5D, 6A, 6B, 7A, 7B, 8A, 8B, 9A, 9B, and 10A-10C, the optical elements 40/44 are described as positioned between an exposure position and a temperature control position. It should be understood that the present invention is not limited to just optical elements used for the fly's eye mirrors of EUV tools. On the contrary, the present invention may be used with any optical system, including but not limited to all the embodiments described and illustrated herein, having an optical element that is positioned between one more operating positions and a temperature control position.

FIG. 11B illustrates a detailed flowchart example of the above-mentioned step 86 in the case of fabricating semiconductor devices. In step 102 (ion implantation step), ions are implanted in the wafer. In step 104 (oxidation step), the substrate wafer surface is oxidized. In step 106 (CVD step), an insulation film is formed on the wafer surface. In step 108 (electrode formation step), electrodes are formed on the wafer by vapor deposition. The above-mentioned steps 102-108 form the preprocessing steps for wafers during wafer processing, and selection is made at each step according to processing requirements.

At each stage of wafer processing, when the above-mentioned preprocessing steps have been completed, the following post-processing steps are implemented. During post-processing, first, in step 110 (photoresist formation step), photoresist is applied to a wafer. Next, in step 112 (exposure step), the lithography tool 10 as described herein is used to transfer the pattern of the reticle 22 to the wafer. Then in step 114 (developing step), the exposed wafer is developed, and in step 116 (etching step), parts other than residual photoresist (exposed material surface) are removed by etching. In step 118 (photoresist removal step), unnecessary photoresist remaining after etching is removed. Multiple circuit patterns are formed by repetition of these preprocessing and post-processing steps. Although not described herein, the fabrication of LCD panels from glass substrates is performed in a similar manner.

Although many of the components and processes are described above in the singular for convenience, it will be appreciated by one of skill in the art that multiple components and repeated processes can also be used to practice the techniques of the system and method described herein. Further, while the invention has been particularly shown and described with reference to specific embodiments thereof, it will be understood by those skilled in the art that changes in the form and details of the disclosed embodiments may be made without departing from the spirit or scope of the invention. For example, embodiments of the invention may be employed with a variety of components and should not be restricted to the ones mentioned above. It is therefore intended that the invention be interpreted to include all variations and equivalents that fall within the true spirit and scope of the invention.

1. An optical system, comprising:
an optical element of a fly's eye mirror;
a temperature control mechanism configured to control the temperature of the optical element of the fly's eye mirror; and
a positioning mechanism configured to selectively thermally couple the optical element with the temperature control mechanism by changing a relative position between the optical element and the temperature control mechanism.

2. The optical system of claim 1, wherein the positioning mechanism is further configured to alternatively position the optical element between:
(i) one or more operational positions; and
(ii) a position in thermal contact with the temperature control mechanism when selectively thermally coupling the optical element with the temperature control mechanism.

3. The optical system of claim 1, wherein the positioning mechanism further comprises two positioning elements for positioning the optical element in at least θX and θY degrees of freedom.

4. The optical system of claim 1, wherein the positioning mechanism further comprises three positioning elements for positioning the optical element in at least θX, θY and Z degrees of freedom.

5. The optical system of claim 1, wherein the temperature control mechanism further comprises a thermal transfer surface that facilitates thermal transfer between the optical element and the temperature control mechanism when selectively thermally coupling the optical element with the temperature control mechanism.

6. The optical system of claim 5, wherein the thermal transfer surface comprises one of the following:
a liquid metal;
a gallium-indium eutectic;
a vacuum grease;
a fluidic layer of any of the noble gasses including but not limited to helium;
a fluidic layer of hydrogen;
an ionic liquid; or a fluidic layer of oxygen.

7. The optical system of claim 2, wherein the positioning mechanism further comprises:
an actuator rod connected to the optical element; and
an actuator connected to the actuator rod, the actuator configured to move the actuator rod so that the optical element is moved to the one or more operational positions.

8. The optical system of claim 7, wherein the positioning mechanism further comprise a joint connecting the actuator rod to the optical element.

9. The optical system of claim 7, wherein the positioning mechanism further comprises a compression member provided between the actuator and the temperature control mechanism.

10. The optical system of claim 9, wherein the actuator is further configured to selectively disengage the actuator rod so that the compression member is free to position the optical element adjacent to or in contact with the temperature control mechanism.

11. The optical system of claim 7, wherein the positioning mechanism further comprises:
an actuator plate for positioning the actuator; and
one or more second actuators configured to move the actuator plate so that the actuator disengages from the actuator rod.

12. The optical system of claim 1, wherein the temperature control mechanism further comprises a thermally conductive plate that is selectively positioned between:
(i) a base plate; or
(ii) adjacent to or in contact with the optical element.

13. The optical system of claim 12, wherein the thermally conductive plate is a copper plate.

14. The optical system of claim 12, wherein the temperature control mechanism further comprises an electro-magnet for selectively positioning the thermally conductive plate between (i) the base plate or (ii) adjacent to or in contact with the optical element.

15. The optical system of claim 14, wherein the temperature control mechanism further comprises a resilient element, operating in cooperation with the electro-magnet, for selectively positioning the thermally conductive plate adjacent to or in contact with the optical element when the electro-magnet is de-activated.

16. The optical system of claim 1, wherein the temperature control mechanism further comprises a post with a thermally conductive surface.

17. The optical system of claim 16, wherein the positioning mechanism and the temperature control mechanism cooperate to alternatively position the optical element between the one or more operational positions and a position in thermal contact with the thermally conductive surface of the post.

18. The optical system of claim 16, further comprising:
a base plate;
a recess formed in the base plate, the thermally conductive surface of the post positioned through the recess.

19. The optical system of claim 16, wherein the positioning mechanism further comprises:
an actuator coupled to a rod-head;
an actuator rod coupled between the optical element and the rod-head, the actuator selectively moving the rod-head and actuator rod to selectively position the optical element to the one or more operational positions.

20. The optical system of claim 19, wherein the temperature control mechanism further comprises a hook-plate to selectively disengage the actuator from the rod-head so that a second actuator can selectively position the optical element adjacent to or in contact with the thermally conductive surface of the post.

21. The optical system of claim 2, further comprising a removing element for selectively removing the optical element from thermal contact with the temperature control mechanism.

22. The optical system of claim 21, wherein the removing element comprises a hook that is configured to selectively hook or unhook the temperature control mechanism.

23. The optical system of claim 22, wherein the hook is configured to be rotated so that it can pass through a recess formed in the temperature control mechanism when unhooking and removing the optical element from the temperature control mechanism.

24. The optical system of claim 2, wherein the positioning element is further configured to return the optical element to the same one or more operational positions after selectively thermally coupling the optical element with the temperature control mechanism.

25. The optical system of claim 1, wherein the positioning mechanism further comprises:
a base plate defining a ball joint;
a positioning plate formed on the base plate;
actuators to move the positioning plate in the X and Y directions; and
a resilient element, coupled between the optical element and the positioning plate, and configured to selectively position the optical element in θX and θY degrees of freedom within the ball joint.

26. The optical system of claim 1, wherein the temperature control mechanism further comprises:
a post having a temperature control surface; and
one or more actuators configured to selectively position the post relative to the optical element so that the optical element is selectively positioned adjacent to or in contact with the thermally conductive surface when selectively thermally coupling the optical element with the temperature control mechanism.

27. The optical system of claim 1, wherein the temperature control mechanism comprises a structure having a fluid inlet and a fluid outlet for circulating fluid adjacent a temperature control surface of the temperature control mechanism.

28. The optical system of claim 1, wherein the temperature control mechanism comprises a structure having two fluid inlets for circulating fluid adjacent a temperature control surface of the temperature control mechanism.

29. The optical system of claim 1, wherein the fly's eye mirror further comprises a plurality of the optical elements arranged in an array.

30. The optical system of claim 29, wherein each of the plurality of optical elements has one of the following shapes:
(i) curved;
(ii) crescent;
(iii) square; or
(iv) rectangular;
(v) circular; or
(vi) oval.

31. The optical system of claim 29, wherein each of the plurality of optical elements is a mirror.

32. The optical system of claim 29, wherein each of the plurality of optical elements comprises copper.

33. (canceled)

34. The optical system of claim 2, wherein the temperature control mechanism is further configured to intermittently control the temperature of a plurality of the optical elements of the fly's eye mirror.

35. An apparatus, comprising:
an EUV light source;
a patterning element defining a pattern;
an illumination unit, including the optical system of claim 1, the illumination unit configured to illuminate the patterning element with EUV light from the source; and
projection optics for projecting the pattern defined by the patterning element onto a substrate.

36. The apparatus of claim 35, wherein the optical system of claim 1 further comprises:
a plurality of the optical elements of the fly's eye mirror;
one or more of the positioning mechanisms configured to position the plurality of optical elements in one or more exposures positions; and
one or more of the temperature control mechanisms configured to intermittently cool the temperature of the plurality of optical elements between exposures.

37. The optical system of claim 2, wherein the temperature control mechanism is configured to intermittently control the temperature of the optical element between the one or more operational positions.
